(19) United States
(12) Patent Application Publication
(10) Pub. No.: US 2025/0174556 A1
(43) Pub. Date: May 29, 2025

(54) SEMICONDUCTOR PACKAGE

(71) Applicant: Samsung Electronics Co., Ltd., Suwon-si (KR)

(72) Inventors: Jitaek OH, Suwon-si (KR); Wonyoung KIM, Suwon-si (KR)

(73) Assignee: Samsung Electronics Co., Ltd., Suwon-si (KR)

(21) Appl. No.: 18/908,351

(22) Filed: Oct. 7, 2024

(30) Foreign Application Priority Data
Nov. 29, 2023 (KR) 10-2023-0169585

(51) Int. Cl. H01L 23/528; H01L 23/00; H01L 23/31; H01L 23/532; H01L 23/544; H01L 25/00; H01L 25/065; H01L 25/18; H10B 80/00

(52) U.S. Cl. CPC H01L 23/5283; H01L 23/5329; H01L 23/544; H01L 24/04; H01L 24/48; H01L 23/3128; H01L 23/562; H01L 23/564; H01L 24/32; H01L 24/49; H01L 24/73; H01L 25/0657; H01L 25/18; H01L 25/50; H01L 2223/5446; H01L 2224/04042; H01L 2224/32145; H01L 2224/32225; H01L 2224/48147; H01L 2224/48227; H01L 2224/49175; H01L 2224/73265; H01L 2225/06506; H01L 2225/0651; H01L 2225/06562; H01L 2924/1815; H10B 80/00

(57) ABSTRACT

A semiconductor package may include a package substrate including substrate pads, semiconductor chips stacked on an upper surface of the package substrate, bonding wirings electrically connecting the semiconductor chips and the substrate pads of the package substrate to each other; and a sealing member on the upper surface of the package substrate and covering the semiconductor chips. Each of the semiconductor chips may include a semiconductor substrate including a first edge and a second edge extending in a first direction and facing each other, a semiconductor chip region and a first scribe lane region and a second scribe lane region adjacent to the second edge, chip pad patterns on a portion of a semiconductor chip region of the semiconductor substrate adjacent to a first edge and along the first edge, and a moat structure on each of the first scribe lane region and the second scribe lane region.

### CROSS-REFERENCE TO RELATED APPLICATION

This application claims priority under 35 USC § 119 to Korean Patent Application No. 10-2023-0169585, filed on Nov. 29, 2023, in the Korean Intellectual Property Office (KIPO), the contents of which are incorporated by reference herein in their entirety.

### BACKGROUND

Various example embodiments of the present disclosure relate to semiconductor packages, particularly, to semiconductor packages including a plurality of chips sequentially stacked on a package substrate. In a multi-chip package (MCP), the plurality of semiconductor chips may be stacked on the package substrate using an adhesive film such as die attach film (DAF) through a die attach process. The plurality of semiconductor chips may be stacked in a cascade manner or a zigzag manner, and some ends of the semiconductor chips may not be aligned to each other. In this case, an upper semiconductor chip may laterally protrude from a lower semiconductor chip, so that an overhang region may be generated. In a high temperature and high humidity environment, an interfacial peeling or crack defects may occur at an edge portion of the lower semiconductor chip corresponding to the overhang region, due to differences of moisture absorption and expansion of a molding member in the semiconductor package.

### SUMMARY

Various example embodiments provide semiconductor packages in which an interfacial peeling or crack defects may be decreased.

According to an example embodiment, a semiconductor package includes a package substrate including substrate pads, a plurality of semiconductor chips stacked on an upper surface of the package substrate, bonding wirings electrically connecting the plurality of semiconductor chips and the substrate pads of the package substrate to each other, and a sealing member on the upper surface of the package substrate and covering the plurality of semiconductor chips, wherein each of the plurality of semiconductor chips comprises a semiconductor substrate including first and second edges and facing each other, the first and second edges extending in a first direction, chip pad patterns on a first portion of a semiconductor chip region of the semiconductor substrate that is adjacent to the first edge, the chip pad patterns being along the first edge, and a moat structure including a plurality of moat structures, the plurality of moat structures including a first moat structure and a second moat structure, the first moat structure being on a first scribe lane region of the semiconductor substrate that is adjacent to the chip pad patterns and the second moat structure being on a second scribe lane region of the semiconductor substrate that is adjacent to the second edge, and wherein the first moat structure extends along the first edge, and the second moat structure extends along the second edge.

According to an example embodiment, a semiconductor package includes a package substrate including substrate pads, a plurality of semiconductor chips stacked on an upper surface of the package substrate, and including chip pad patterns, moat structures, and test element group patterns, bonding wirings electrically connecting chip pad patterns of the plurality of semiconductor chips and the substrate pads of the package substrate to each other, and a sealing member on the upper surface of the package substrate and covering the plurality of semiconductor chips, wherein each of the plurality of semiconductor chips includes a semiconductor chip region and a scribe lane region surrounding the semiconductor chip region, the semiconductor chip region including a first edge, a second edge, a third edge, and a fourth edge, the first and second edges extending in a first direction and facing each other, the third and fourth edges extending in a second direction perpendicular to the first direction and facing each other, wherein the chip pad patterns are on a portion of the semiconductor chip region that is adjacent to the first edge, and the chip pad patterns are spaced apart from each other in the first direction, wherein the scribe lane region including a first scribe lane region adjacent to the chip pad patterns and a second scribe lane region adjacent to the second edge of the semiconductor chip region, wherein the moat structures include a first moat structure and a second moat structure, the first moat structure being on the first scribe lane region, the second moat structure being on the second scribe lane region, and each of the moat structures extending in the first direction, and wherein the test element group patterns are on one or more scribe lane regions other than the first scribe lane region and the second scribe lane region.

According to an example embodiment, a semiconductor package includes a package substrate including substrate pads, a plurality of semiconductor chips stacked on an upper surface of the package substrate, some edges of adjacent semiconductor chips from among the plurality of semiconductor chips are offset from each other, bonding wirings electrically connecting the plurality of semiconductor chips and the substrate pads of the package substrate to each other, and a sealing member on the upper surface of the package substrate and covering the plurality of semiconductor chips, wherein at least one of the plurality of semiconductor chips comprises chip pad patterns along a first edge of a semiconductor chip region thereof, moat structures on a first scribe lane region adjacent to the chip pad patterns and a second scribe lane region adjacent to a second edge facing the first edge of the semiconductor chip region, and a test element group pattern on a third scribe lane region between the moat structures.

According to an example embodiment, in at least one of the semiconductor chips included in the semiconductor package, the moat structure may be disposed on the scribe lane region facing each other, which may correspond to the overhang region. In addition, the test element group (TEG) pattern may be disposed on the scribe lane region facing each other, which may not correspond to the overhang region. The moat structure may mitigate or prevent from a progress of an interfacial peeling or a crack from the edge of the semiconductor chip to an inside of the semiconductor chip. The moat structure may be disposed at the overhang region where interfacial peelings or cracks frequently occur in the semiconductor chips of the semiconductor package, so that the interfacial peeling or cracks in the semiconductor chip may be decreased.

### BRIEF DESCRIPTION OF THE DRAWINGS

Various example embodiments will be more clearly understood from the following detailed description taken in conjunction with the accompanying drawings. FIGS. 1 to 25 represent various non-limiting, example embodiments as described herein.

FIG. 1 is a cross-sectional view illustrating a semiconductor package according to an example embodiment;

FIG. 2 is a plan view illustrating a semiconductor package according to an example embodiment;

FIG. 3 is a plan view illustrating semiconductor chips included in a semiconductor package according to an example embodiment;

FIG. 4 is a plan view illustrating semiconductor chips included in a semiconductor package according to an example embodiment;

FIG. 5 is a plan view illustrating semiconductor chips included in a semiconductor package according to an example embodiment;

FIGS. 6 and 7 are cross-sectional views of portions of semiconductor chips included in a semiconductor package according to an example embodiment, respectively;

FIG. 8 is a view illustrating a semiconductor substrate on which semiconductor chips are formed, and an enlarged view of a portion of the semiconductor substrate, according to an example embodiments;

FIGS. 9 to 22 are cross-sectional views and plan views for illustrating a method of manufacturing a semiconductor package according to an example embodiment;

FIG. 23 is a cross-sectional view showing a semiconductor package according to an example embodiment;

FIG. 24 is a cross-sectional view illustrating a semiconductor package according to an example embodiment; and

FIG. 25 is a cross-sectional view illustrating a semiconductor package according to an example embodiment.

### DETAILED DESCRIPTION

Hereinafter, various example embodiments will be described in detail with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

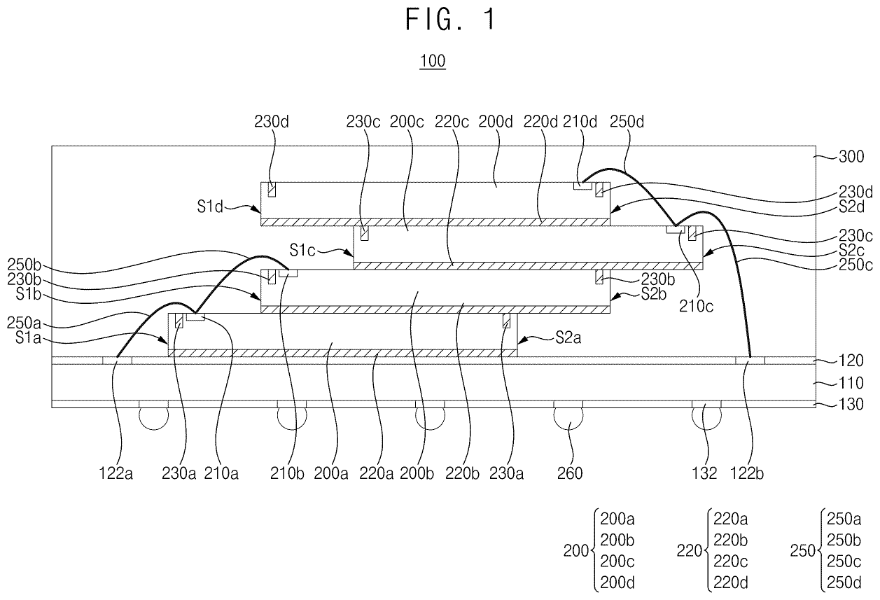

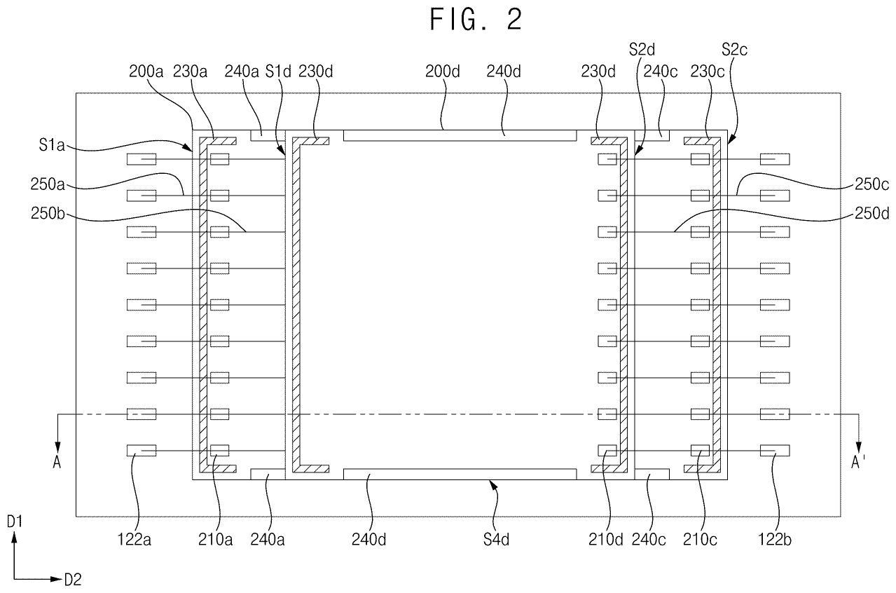

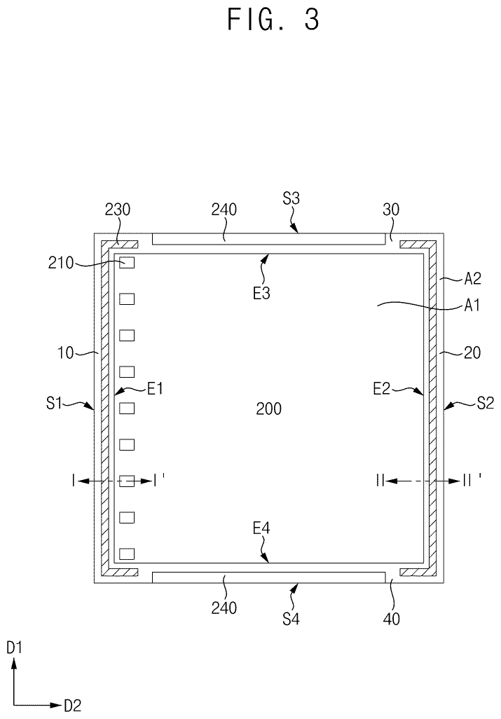

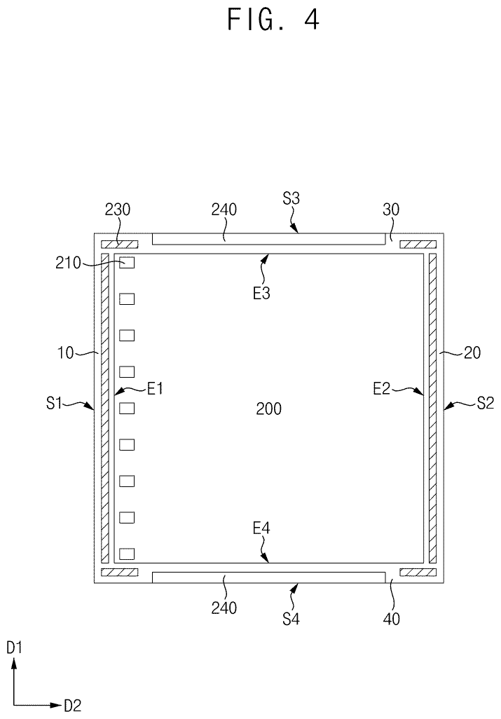

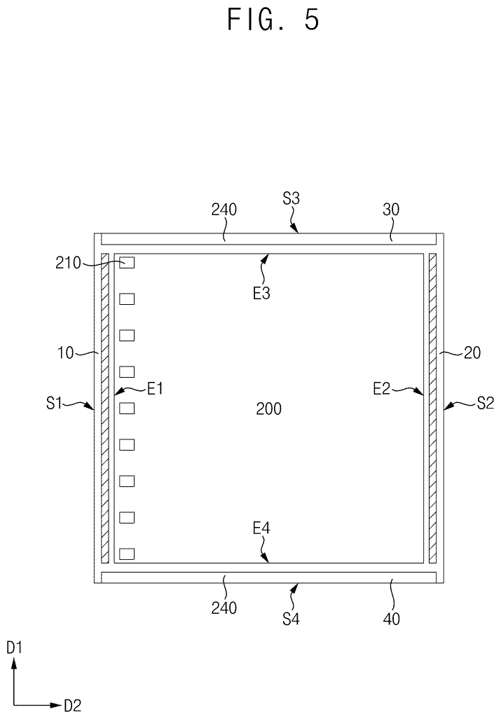

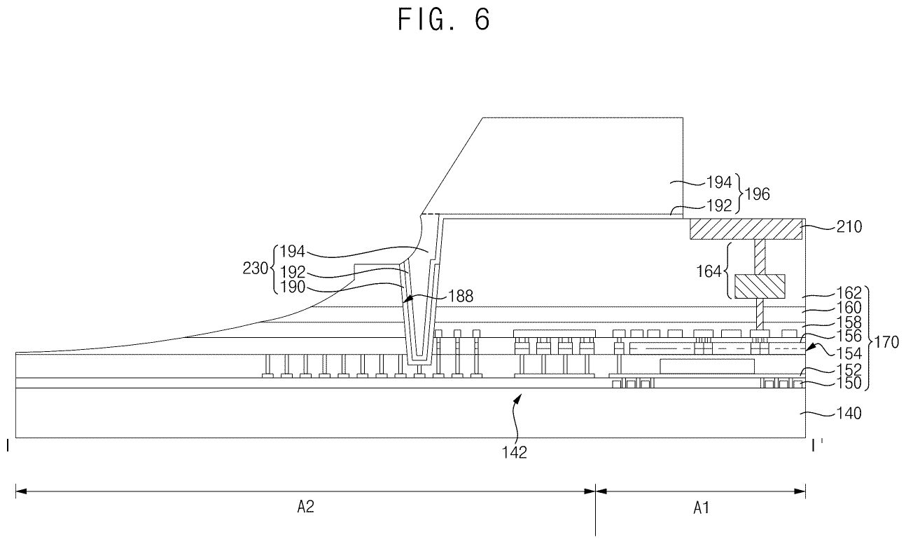

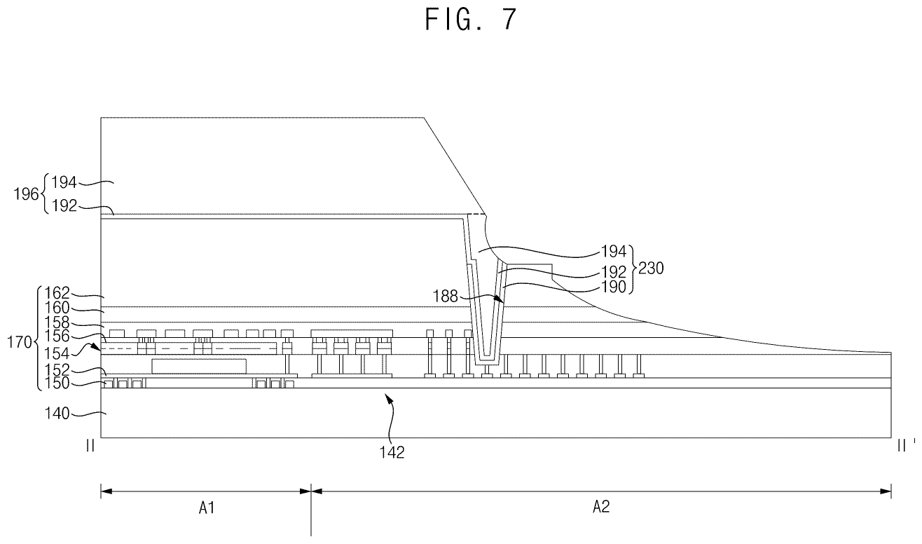

FIG. 1 is a cross-sectional view illustrating a semiconductor package according to an example embodiment. FIG. 2 is a plan view illustrating a semiconductor package according to an example embodiment. FIG. 3 is a plan view illustrating semiconductor chips included in a semiconductor package according to an example embodiment. FIG. 4 is a plan view illustrating semiconductor chips included in a semiconductor package according to an example embodiment. FIG. 5 is a plan view illustrating semiconductor chips included in a semiconductor package according to an example embodiment. FIGS. 6 and 7 are cross-sectional views of portions of semiconductor chips included in a semiconductor package according to an example embodiment, respectively.

FIG. 1 is a cross-sectional view taken along line A-A′ in FIG. 2. FIG. 6 is a cross-sectional view taken along line I-I′ of FIG. 3. FIG. 7 is a cross-sectional view taken along line II-II′ of FIG. 3.

Referring to FIGS. 1, 2 and 3, a semiconductor package 100 may include a package substrate 110, a plurality of semiconductor chips 200 on the package substrate 110 and stacked in a vertical direction, adhesive members 220, bonding wirings 250 and a sealing member 300. The bonding wiring 250 may be conductive connection members that electrically connect the semiconductor chips 200 to the package substrate 110. The semiconductor package 100 may further include external connection members 260.

The semiconductor package 100 may be a multi-chip package (MCP) including semiconductor chips 200 of the same type or different types. The semiconductor package may include a plurality of semiconductor chips stacked on and/or arranged in one package, and may serve as a system in package (SIP) having an independent function.

The semiconductor chips 200 may include a logic chip including logic circuits and/or a memory chip including memory circuits. The logic chip may be a controller that controls memory chips. The logic chip may be a processor chip, for example, an ASIC or an application processor (AP) as a host such as a CPU, GPU, or SOC. The memory chip may include, for example, volatile memory devices such as a SRAM device, a DRAM device, or non-volatile memory devices such as a flash memory device, a PRAM device, an MRAM devices, and an RRAM device.

In some example embodiments, the package substrate 110 may be a substrate having an upper surface and a lower surface facing each other. The package substrate 110 may include, for example, a printed circuit board (PCB), a flexible board, a tape board, etc. The printed circuit board may be a multilayer circuit board including via contact plugs and various circuits therein. The package substrate 110 may include internal wirings for electrical connection with the semiconductor chips 200. First substrate pads 122a and second substrate pads 122b may be disposed on the upper surface of the package substrate 110. The first and second substrate pads 122a and 122b may be electrically connected to the internal wirings.

A first insulation layer 120 may be on the upper surface of the package substrate 110 to expose each of the first and second substrate pads 122a and 122b. In some example embodiments, the first insulation layer 120 may cover an entire upper surface of the package substrate 110 excluding the first and second substrate pads 122a and 122b. For example, the first insulation layer 120 may include a solder resist.

The semiconductor chips 200 may be mounted on the package substrate 110. A semiconductor substrate on which the semiconductor chips are manufactured may be cut by a sawing process to form the semiconductor chips 200.

Each of the semiconductor chips 200 may be formed by a sawing process of a semiconductor substrate on which the semiconductor chips are manufactured. For example, the semiconductor substrate may include chip regions A1 on which circuit patterns for forming the semiconductor chip 200 are formed, and a scribe lane region A2 disposed between the chip regions A1 and surrounding the chip regions A1. The scribe lane region A2 of the semiconductor substrate may be cut by the sawing process, the so that individual semiconductor chips (hereinafter referred to as semiconductor chips) may be formed.

As shown in FIG. 3, in a plan view, the semiconductor chips 200 to be mounted on the package substrate 110 may have a rectangular shape having four sidewalls. The semiconductor chip 200 may include a first sidewall S1, a second sidewall S2, a third sidewall S3 and a fourth sidewall S4. The first sidewall S1 and the second sidewall S2 may extend in the first direction D1, and may face each other in the second direction D2 perpendicular to the first direction D1. The third sidewall S3 and the fourth sidewall S4 may extend in the second direction D2, and may be disposed to face each other in the first direction D1.

In FIG. 1, the semiconductor package 100 may include four semiconductor chips 200 stacked. The four semiconductor chips 200 are referred to as a first semiconductor chip 200a, a second semiconductor chip 200b, a third semiconductor chip 200c and fourth semiconductor chip 200d sequentially in the vertical direction from a bottom to a top, respectively. Additionally, the same elements included in the semiconductor chips are referred to as first to fourth elements depending on each of vertical levels.

However, the number of semiconductor chips 200 included in the semiconductor package 100 may not be limited to thereto.

A first adhesive member 220a may be interposed between the package substrate 110 and the first semiconductor chip 200a, so that the first semiconductor chip 200a may be attached to the package substrate 110. The first semiconductor chip 200a may include first chip pad patterns 210a and a first moat structure 230a. A moat structure in each of the semiconductor chips may reduce or prevent a crack due to a hygro-swelling (or a hygroscopic expansion) from progressing.

The second semiconductor chip 200b may be stacked on the first semiconductor chip 200a. A second adhesive member 220b may be interposed between the first semiconductor chip 200a and the second semiconductor chip 200b, so that the second semiconductor chip 200b may be attached to the first semiconductor chip 200a. The second semiconductor chip 200b may include second chip pad patterns 210b and a second moat structure 230b.

In some example embodiments, an end of the second semiconductor chip 200b may not be aligned with (e.g., may be offset from) an end of the first semiconductor chip 200a in the vertical direction. In some example embodiments, the second semiconductor chip 200b may be stacked on the first semiconductor chip 200a to have a cascade structure (or a cascade manner). The second semiconductor chip 200b may be offset in the second direction D2 with the first semiconductor chip 200a. For example, the second semiconductor chip 200b may be offset in the second direction D2 so that the first chip pad patterns 210a of the first semiconductor chip 200a may be exposed.

In some example embodiments, the first chip pad patterns 210a may be disposed along an upper surface adjacent to the first sidewall Sla of the first semiconductor chip 200a, and the second chip pad patterns 210b may be disposed along an upper surface adjacent to the first sidewall S1b of the second semiconductor chip 200b. The first chip pad patterns 210a may be disposed on a first semiconductor chip region of the first semiconductor chip 200a, and the second chip pad patterns 210b may be disposed on a second semiconductor chip region of the second semiconductor chip 200b. Accordingly, the first and second chip pad patterns 210a and 210b may be exposed at the upper surfaces adjacent to the first sides Sla and S1b of the first and second semiconductor chips 200a and 200b, respectively.

The first semiconductor chip 200a may protrude in a lateral direction (e.g., in the second direction) from the first sidewall S1b of the second semiconductor chip 200b. The second semiconductor chip 200b may protrude in the lateral direction from the second sidewall S2a of the first semiconductor chip 200a. A portion adjacent to the second sidewall S2a and the second sidewall S2a of the first semiconductor chip 200a below the protruding second semiconductor chip 200b may be a first overhang region.

The first semiconductor chip 200a and the second semiconductor chip 200b may be electrically connected to the package substrate 110 by a first bonding wiring 250a and a second bonding wiring 250b. The first bonding wiring 250a may contact the first chip pad pattern 210a and the first substrate pad 122a, and thus the first chip pad pattern 210a and the first substrate pad 122a may be electrically connected to each other. The second bonding wiring 250b may contact the second chip pad pattern 210b of the second semiconductor chip 200b and the first chip pad pattern 210a of the first semiconductor chip 200a, and thus the second chip pad pattern 210b and the first chip pad pattern 210a may be electrically connected to each other. The first and second chip pad patterns 210a and 210b and the first substrate pad 122a may be electrically connected to each other by the first and second bonding wirings 250a and 250b.

The third semiconductor chip 200c may be stacked on the second semiconductor chip 200b. A third adhesive member 220c may be interposed between the second semiconductor chip 200b and the third semiconductor chip 200c so that the third semiconductor chip 200c may be attached to the second semiconductor chip 200b. The third semiconductor chip 200c may include third chip pad patterns 210c and a third moat structure 230c.

An end in the second direction D2 of the third semiconductor chip 200c may not be aligned with (e.g., may be offset from) an end in the second direction D2 of the fourth semiconductor chip 200d in the vertical direction. In some example embodiments, the third semiconductor chip 200c may be stacked on the second semiconductor chip 200b to have the cascade structure. In some example embodiments, the ends in the second direction D2 of a stacked structure of the first semiconductor chip 200a, the second semiconductor chip 200b, and the third semiconductor chip 200c may have a step shape. The third semiconductor chip 200c may be offset in the second direction with the second semiconductor chip 200b. The third semiconductor chip 200c may be offset in the second direction D2 so as to expose the second chip pad patterns 210b of the second semiconductor chip 200b.

In some example embodiments, the third chip pad patterns 210c may be disposed along an upper surface adjacent to the second sidewall S2c of the third semiconductor chip 200c. Accordingly, the third chip pad patterns 210c may be exposed at the upper surface adjacent to the second sidewall S2c of the third semiconductor chip 200c.

The fourth semiconductor chip 200d may be stacked on the third semiconductor chip 200c. A fourth adhesive member 220d may be interposed between the third semiconductor chip 200c and the fourth semiconductor chip 200d so that the fourth semiconductor chip 200d may be attached to the third semiconductor chip 200c. The fourth semiconductor chip 200d may include fourth chip pad patterns 210d and a fourth moat structure 230d. The third chip pad patterns 210c may be disposed on a third semiconductor chip region of the third semiconductor chip 200c, and the fourth chip pad patterns 210d may be disposed on a fourth semiconductor chip region of the fourth semiconductor chip 200d.

An end in the second direction D2 of the fourth semiconductor chip 200d may not be aligned with (e.g., may be offset from) an end in the second direction D2 of the third semiconductor chip 200c in the vertical direction. In some example embodiments, the fourth semiconductor chip 200d may be offset in the second direction D2 on the third semiconductor chip 200c. The fourth semiconductor chip 200d may be offset in the second direction D2 so as to expose the third chip pad patterns 210c of the third semiconductor chip 200c.

In some example embodiments, the fourth chip pad patterns 210d may be disposed along an upper surface adjacent to the second sidewall S2d of the fourth semiconductor chip 200d. Accordingly, the fourth chip pad patterns 210d may be exposed at the upper surface adjacent to the second sidewall S2d of the fourth semiconductor chip 200d.

The third semiconductor chip 200c may protrude in the lateral direction (e.g., in the second direction) from the second sides S2b and S2d of the second and fourth semiconductor chips 200b and 200d. The fourth semiconductor chip 200d may protrude in the lateral direction from the first sidewall S1c of the third semiconductor chip 200c. A portion adjacent to the second sidewall S2b and the second sidewall S2b of the second semiconductor chip 200b below the protruding third semiconductor chip 200c may be a second overhang region. A portion adjacent to the first sidewall S1b and the first sidewall S1b of the second semiconductor chip 200b below the protruding fourth semiconductor chip 200d may be a third overhang region. A portion adjacent to the first sidewall S1c and the first sidewall Sc of the third semiconductor chip 200c below the protruding fourth semiconductor chip 200d may be a fourth overhang region. The overhang regions of the semiconductor chips 200 may be positioned at regions adjacent to edges in the second direction D2 of the semiconductor chips 200.

The third semiconductor chip 200c and the fourth semiconductor chip 200d may be electrically connected to the package substrate 110 by a third bonding wiring 250c and a fourth bonding wiring 250d. The third bonding wiring 250c may contact the third chip pad pattern 210c and the second substrate pad 122b, and thus the third chip pad pattern 210c and the second substrate pad 122b may be electrically connected to each other. The fourth bonding wiring 250d may contact the fourth chip pad pattern 210d of the fourth semiconductor chip 200d and the third chip pad pattern 210c of the third semiconductor chip 200c, and thus the fourth chip pad pattern 210d and the third chip pad pattern 210c may be electrically connected to each other.

The sealing member 300 may be on the upper surface of the package substrate 110, and the sealing member 300 may cover the first to fourth semiconductor chips 200a, 200b, 200c, and 200d and the first to fourth bonding wirings 250a, 250b, 250c, and 250d on the upper surface of the package substrate 110. The sealing member 300 may include a thermosetting resin, for example, epoxy mold compound (EMC).

An external connection pad 132 may be on a lower surface of the package substrate 110. Electrical signal may be input and or output through the external connection pad 132. The external connection pads 132 may be exposed by a second insulation layer 130. The second insulation layer 130 may include a silicon oxide layer, a silicon nitride layer, or a silicon oxynitride layer. An external connection member 260 may be disposed on the external connection pad 132 of the package substrate 110 for electrical connection with an external device. For example, the external connection member 260 may include a solder ball. In some example embodiments, the semiconductor package 100 may be mounted on a module substrate (not shown) using the solder balls to form a memory module.

The hygro-swelling of the sealing member 300 may be generated under a high temperature and a high humidity condition. Crack defects may occur in overhang regions of the semiconductor chips 200 due to an expansion of the sealing member 300. Accordingly, the crack defects due to the hygro-swelling may occur at edge portions of the semiconductor chips corresponding to the overhang regions of the semiconductor chips 200.

Accordingly, the semiconductor chips 200 may be designed so as to reduce the occurrence of crack defects. Hereinafter, the semiconductor chips 200 included in the semiconductor package 100 may be described in more detail with reference to FIGS. 3 to 5. For example, the semiconductor chip 200 shown in FIG. 3 may collectively refer to first to fourth semiconductor chips included in the semiconductor package 100.

Referring to FIG. 3, the semiconductor chip 200 may include a chip region A1 and a scribe lane region A2.

In the plan view, the chip region A1 of the semiconductor chip 200 may have a rectangular shape. The chip region A1 may have a first edge E1 adjacent to the first sidewall S1, a second edge E2 adjacent to the second sidewall S2, and a third edge E3 adjacent to the third sidewall S3, and a fourth edge E4 adjacent to the fourth sidewall S4.

The scribe lane region A2 may have a square ring shape surrounding the chip region A1. The scribe lane region A2 may include a first region 10 adjacent to the first sidewall S1, a second region 20 adjacent to the second sidewall S2, and a third region 30 adjacent to the third sidewall S3 and a fourth region 40 adjacent to the fourth sidewall S4.

The chip pad patterns 210 may be disposed along one of the edges of the chip region A1 in the semiconductor chip 200. For example, the chip pad patterns 210 may be the chip region adjacent to the first edge E1, and may be spaced apart from each other in the first direction D1. The first chip pad patterns 210a may be electrically connected to circuit patterns included in the semiconductor chip 200.

A moat structure 230 may be disposed on the scribe lane region A2. Further, test element group (TEG) patterns 240 may be disposed on the scribe lane region A2. In the scribe lane region A2, the moat structure 230 and the test element group pattern 240 may not be arranged together in a width direction of the scribe lane region A2.

The moat structure 230 may be disposed on the scribe lane region A2 adjacent to the chip pad patterns 210 and on the scribe lane region A2 facing the chip pad patterns 210. For example, the moat structure 230 may be disposed on the first and second regions 10 and 20 within the scribe lane region A2. The moat structure 230 may alleviate or prevent moisture absorption. Further, the moat structure 230 may block or prevent the crack defects generated from the edges of the semiconductor chip 200 from progressing into an inside of the semiconductor chip region A1.

The moat structure 230 may continuously extend in an arrangement direction of the chip pad patterns 210 (e.g., the first direction). In some example embodiments, the moat structure 230 may be spaced apart from the first edge E1, and may be continuously extend along an entirety of the first edge E1. Additionally, the moat structure 230 may be spaced apart from the second edge E2, and may be continuously extend along an entirety of the second edge E2.

In some example embodiments, the moat structure 230 on the first region 10 may be symmetrical to the moat structure 230 on second region 20.

In some example embodiments, as shown in FIG. 3, the moat structure 230 may extend in a first direction D1 within the first region 10, and both ends in the first direction D1 of the moat structure 230 may extend in the second direction D2 within edges of the third and fourth regions 30 and 40. In addition, the moat structure 230 may extends in the first direction D1 within the second region 20, and both ends in the first direction D1 of the moat structure 230 may extend in the second direction D2 within edges of the third and fourth regions 30 and 40.

In some example embodiments, as shown in FIG. 4, the moat structure 230 may extend in the first direction D1 within the first and second regions 10 and 20. In addition, the moat structure 230 may extend in the second direction D2 within edges of the third and fourth regions 30 and 40. The moat structure 230 on the third and fourth regions 30 and 40 may be spaced apart from the moat structure 230 on the first and second regions 10 and 20.

In some example embodiments, as shown in FIG. 5, the moat structure 230 may extend in the first direction D1 within the first and second regions 10 and 20. The moat structure 230 may not be formed within the third and fourth regions 30 and 40.

The moat structure 230 may have a structure including a protective insulation material filled in a trench on the scribe lane region A2 of the semiconductor chip 200.

The test element group pattern 240 may be disposed on the scribe lane region A2 where the moat structure 230 is not formed. The test element group pattern 240 may be disposed between the moat structures 230.

In some example embodiments, the test element group pattern 240 may be disposed on the third and fourth regions 30 and 40 of the scribe lane region A2. The test element group pattern 240 may include test circuit patterns for testing of circuits included in the semiconductor chip 200.

Hereinafter, a vertical structure of the moat structure included in the semiconductor chip 200 may be described with reference to FIGS. 6 and 7.

Referring to FIGS. 6 and 7, a circuit pattern structure 170 and a chip pad pattern 210 may be disposed on the chip region A1 of the semiconductor substrate 140.

In some example embodiments, the circuit pattern structure 170 may include lower cell structures 150, a lower insulating interlayer 152, a first upper metal interconnection structure 154, an intermetallic insulation layer 156, a first upper insulation layer 158, a second upper insulation layer 160, an uppermost insulation layer 162, and a second upper metal wiring pattern 164. A capping insulation layer 192 and an upper protective layer 194 may be further formed on the uppermost insulation layer 162.

The lower cell structures 150 may configure memory cells. The lower insulating interlayer 152 may cover the lower cell structure 150. The first upper metal interconnection structure 154 may be on the lower insulating interlayer 152, and may be electrically connected to the memory cells. The intermetallic insulation layer 156 may cover metal wirings included in the first upper metal interconnection structure 154. The first and second upper insulation layers 158 and 160 and the uppermost insulation layer 162 may cover the intermetallic insulation layer 156. In some example embodiments, the first upper insulation layer 158 may include silicon nitride. The second upper insulation layer 160 may include silicon oxide. The uppermost insulation layer 162 may include silicon oxide. For example, the uppermost insulation layer 162 may include tetraorthosilicate (TEOS) material. The second upper metal wiring pattern 164 may be within the first and second upper insulation layers 158 and 160 and the uppermost insulation layer 162, and may be electrically connected to the first upper metal interconnection structure 154.

The chip pad pattern 210 may be disposed within the uppermost insulation layer 162. An upper surface of the chip pad pattern 210 may not be covered by the uppermost insulation layer 162. The upper surface of the chip pad pattern 210 may be coplanar with an upper surface of the uppermost insulation layer 162.

A lower structure and a moat structure 230 may be disposed on the scribe lane region A2 of the semiconductor substrate 140.

The lower structure may include a scribe lane guard ring 142, a test element group pattern 240 (referred to as FIG. 3), the lower insulating interlayer 152, the intermetallic insulation layer 156, the first upper insulation layer 158, the second upper insulation layer 160, and the uppermost insulation layer 162.

The scribe lane guard ring 142 may be disposed on the scribe lane region A2 adjacent to the chip region A1. In some example embodiments, the scribe lane guard ring 142 may include metal patterns stacked in the vertical direction.

The test element group pattern 240 may include test circuit patterns for testing of circuits included in the semiconductor chip.

The lower insulating interlayer 152, the intermetallic insulation layer 156, the first upper insulation layer 158, the second upper insulation layer 160, and the uppermost insulation layer 162 on the scribe lane region A2 may be the same as or substantially similar to the lower insulating interlayer 152, the intermetallic insulation layer 156, the first upper insulation layer 158, the second upper insulation layer 160 and the uppermost insulation layer 162 on the chip region A1, respectively.

In some example embodiments, the uppermost insulation layer 162 on the scribe lane region A2 adjacent to the chip region A1 may have a top surface height the same as a top height of the uppermost insulation layer 162 on the chip region A1. However, a height of an upper surface of the uppermost insulation layer 162 may gradually decrease in the scribe lane region A2 as a distance between the chip region A1 and the scribe lane A2 increases.

Accordingly, the upper surface of the uppermost insulation layer 162 of the chip region A1 and the scribe lane region A2 adjacent to the chip region A1 may have substantially flat surface, and may have a first height. The upper surface of the uppermost insulation layer 162 on the scribe lane region A2 except for a portion adjacent to the chip region A1 may be inclined in a direction away from the chip region A1, and the upper surface of the uppermost insulation layer 162 on the scribe lane region A2 spaced apart from the chip region A1 may have a second height lower than the first height.

A trench 188 may be on the lower structure of the scribe lane region A2. The trench 188 may extend from an upper portion of the lower structure to an inner portion of the lower structure.

The trench 188 may not extend to the upper surface of the semiconductor substrate 140 in the vertical direction. In some example embodiments, the trench 188 may pass through at least the uppermost insulation layer 162 and the first and second upper insulation layers 158 and 160. Accordingly, a bottom of the trench 188 may be spaced apart from the upper surface of the semiconductor substrate 140, and may be higher than the upper surface of the semiconductor substrate 140. In some example embodiments, the trench 188 may be spaced apart from the scribe rain guard ring 142 in a horizontal direction.

The trench 188 may be disposed in the first and second regions 10 and 20 (referred to as FIG. 3) of the scribe lane region A2. The trench 188 may continuously extend in the first direction D1. That is, the trench 188 may be positioned at a region adjacent to the first edge E1 where the chip pad patterns 210 are formed and at a region adjacent to the second edge E2 facing the first edge E1.

The trench 188 may be formed by etching a portion having the first height and a portion having the second height of the uppermost insulation layer 162 together. Accordingly, the height of the upper surface of the trench 188 may not be constant.

An inner portion of the trench 188 may be filled with a protective insulation material, and the protective insulation material filling the trench 188 may serve as the moat structure 230.

In some example embodiments, the moat structure 230 may include a metal barrier pattern 190, a capping insulation layer 192, and an upper protective layer 194. The metal barrier pattern 190 may be conformally formed on a lower sidewall and a bottom of the trench 188. The capping insulation layer 192 may be conformally formed on surfaces of the metal barrier pattern 190 and the uppermost insulation layer 162. The upper protective layer 194 may be formed on the capping insulation layer 192 to fill the trench 188. The upper protective layer 194 may cover the capping insulation layer 192.

The metal barrier pattern 190 may include, for example, aluminum or copper. The capping insulation layer 192 may include, for example, silicon nitride. The upper protective layer 194 may include, for example, photosensitive polyimide (PSPI).

The moat structure 230 may extend from an upper portion of the lower structure to an inner portion of the lower structure. In some example embodiments, the moat structure 230 may pass through at least the uppermost insulation layer 162 and the first and second upper insulation layers 158 and 160. The moat structure 230 may not extend to the upper surface of the semiconductor substrate 140. Accordingly, the moat structure 230 may be spaced apart from the upper surface of the semiconductor substrate 140. The moat structure 230 may be positioned over the upper surface of the semiconductor substrate 140. In some example embodiments, the moat structure 230 may be spaced apart from the scribe lane guard ring 142.

In some example embodiments, a width in the second direction D2 of the moat structure 230 may be in the range of about 8 μm to about 10 μm.

The capping insulation layer 192 and the upper protective layer 194 that are disposed on the upper surface of the moat structure 230 and the uppermost insulation layer 162 may serve as the upper protective layer structure 196. The capping insulation layer 192 and the upper protective layer 194 included in the upper protective layer structure 196 and the capping insulation layer 192 and the upper protective layer 194 included in the moat structure 230 may have the same materials, respectively.

The test element group pattern 240 may be disposed on the scribe lane region A2 of the semiconductor substrate 140 where the moat structure 230 is not formed. The test element group pattern 240 may be disposed on the third and fourth regions 30 and 40 of the scribe lane region A2.

As described above, in the semiconductor chip 200, the moat structure 230 may be disposed on the scribe lane region A2 adjacent to a region where the chip pad patterns 210 are formed and on the scribe lane region A2 opposite thereto. At least a portion of the region where the moat structure 230 is disposed may correspond to the overhang region of each of semiconductor chips 200 within the semiconductor package 100. The moat structure 230 may be disposed on the overhang region of each of the semiconductor chips 200.

The moat structure 230 may be disposed at the portion of the semiconductor chip 200 where crack defects due to the hygro-swelling most frequently occur, so that the crack defects of the semiconductor chip 200 may be decreased. Additionally, the test element group pattern 240 may be disposed on the scribe lane region A2 where the moat structure 230 is not formed.

In some example embodiments, the moat structure 230 and the test element group pattern 240 as described above may be disposed on the scribe lane region A2 of each of the first to fourth semiconductor chips 200a, 200b, 200c, and 200d included in the semiconductor package 100.

In some the semiconductor chips, a progress of the crack defects due to the hygro-swelling may be blocked by the moat structure so that the crack defects may not extend into an inner portion of the chip region. Accordingly, defects of the semiconductor package due to the crack defects may be decreased.

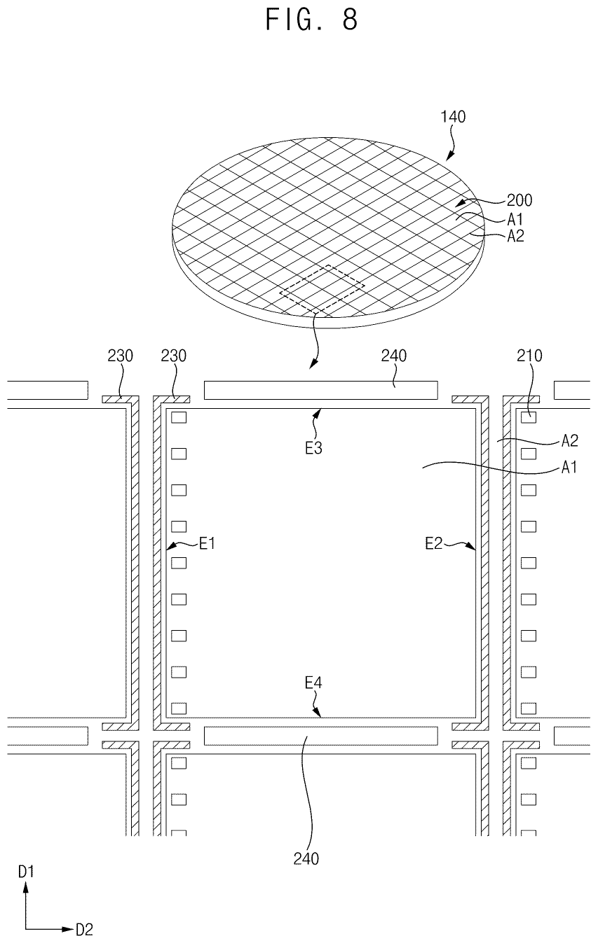

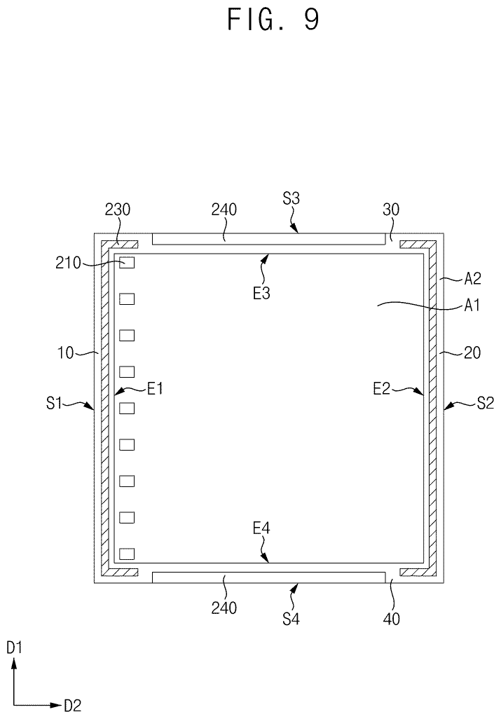

FIG. 8 is a view illustrating a semiconductor substrate on which semiconductor chips are formed, and an enlarged view of a portion of the semiconductor substrate, according to an example embodiment. FIGS. 9 to 22 are cross-sectional views and plan views for illustrating a method of manufacturing a semiconductor package according to an example embodiment.

Referring to FIG. 8, semiconductor chips 200 to be mounted on a package substrate may be manufactured on a semiconductor substrate. The semiconductor chips 200 may be manufactured on the semiconductor substrate by performing manufacturing processes of the semiconductor chips 200. The semiconductor substrate may include chip regions A1 on which circuit patterns constituting the semiconductor chip 200 are formed, and a scribe lane region A2 disposed between the chip regions A1 and surrounding the chip region A1.

A circuit pattern structure 170 and chip pad patterns 210 may be disposed on the chip region A1 of the semiconductor substrate 140. The chip pad patterns 210 may be adjacent to the first edge E1 of the chip region A1, and may be spaced apart from each other in the first direction D1.

In some example embodiments, the circuit pattern structure 170 may include lower cell structures 150, a lower insulating interlayer 152, a first upper metal interconnection structure 154, an intermetallic insulation layer 156, a first upper insulation layer 158, a second upper insulation layer 160, an uppermost insulation layer 162, and a second upper metal wiring pattern 164. A capping insulation layer 192 and an upper protective layer 194 may be further formed on the uppermost insulation layer 162.

A lower structure and a moat structure 230 may be formed on the scribe lane region A2.

The lower structure may include a scribe lane guard ring 142, a test element group pattern 240 (referred to as FIG. 3), the lower insulating interlayer 152, the intermetallic insulation layer 156, the first upper insulation layer 158, and the second upper insulation layer 160, and the uppermost insulation layer 162.

The moat structure 230 may be formed on the scribe lane region A2 adjacent to a region where the chip pad patterns 210 are formed, and on the scribe lane region A2 opposite to the region where the chip pad patterns 210 are formed. The moat structure 230 may be disposed on the first and second regions 10 and 20 within the scribe lane region A2. The moat structure 230 may extend in an arrangement direction of the chip pad patterns 210 (e.g., the first direction).

The test element group pattern 240 may be formed on the scribe lane region A2 where the moat structure 230 is not formed. The test element group pattern 240 may be formed on the third and fourth region 30 and 40 within the scribe lane region A2.

The moat structure 230 may be spaced apart from the first edge E1, and may continuously extend along an entirety of the first edge E1. The moat structure may extend in the first direction D1. The moat structure 230 may be spaced apart from the second edge E2, and may be continuously extend along an entirety of the second edge E2. The moat structure may extend in the first direction D1. The moat structure 230 may uninterruptedly extend (e.g., extend continuously) on the first region 10, and may uninterruptedly extend (e.g., extend continuously) on the second region 20.

In some example embodiments, the moat structure 230 on the first region 10 may be symmetrical to the moat structure 230 on the second region 20.

The lower structure may be etched to form a trench 188, and then a protective insulation material may fill the trench 188 to form the moat structure 230.

For example, the trench 188 extending from an upper portion of the lower structure to an inner portion of the lower structure in the vertical direction may be formed. The trench 188 may continuously extend in the first direction D1 on the first region 10 and the second region 20. The trench 188 may not extend to the upper surface of the semiconductor substrate 140 in the vertical direction.

A portion having the first height and a portion having the second height of the uppermost insulation layer 162 may be etched together to form the trench 188. Accordingly, a height of an upper portion of the trench 188 may not be constant. For example, the height of the upper portion of the trench 188 adjacent to the chip pad patterns 210 may be relatively high.

The protective insulation material may fill the trench 188 to form the moat structure 230. In some example embodiments, as shown in FIGS. 6 and 7, the moat structure 230 may include a metal barrier pattern 190, a capping insulation layer 192, and an upper protective layer 194. The metal barrier pattern 190 may be conformally formed on a lower sidewall and a bottom of the trench 188. The metal barrier pattern 190 may be conformally formed on the metal barrier pattern 190 and a sidewall of the trench 188. The upper protective layer 194 may be formed on metal barrier pattern 190 to fill the trench 188.

The capping insulation layer 192 and the upper protective layer 194 may be also formed on the upper surface of the moat structure 230 and the upper surface of the uppermost insulation layer 162.

In some example embodiments, a width of the scribe lane region A2 of the semiconductor substrate 140 before a sawing process may be in the range of about 55 μm to about 65 μm. In some example embodiments, a width of the region where the test element group patterns 240 are formed may be in the range of about 50 μm to about 55 μm. Two moat structures 230 may be disposed on the scribe lane region A2 of the semiconductor substrate 140 in the second direction, before the sawing process.

In some example embodiments, a width of each of the moat structures 230 may be in the range of about 8 μm to about 10 μm. When the width of the moat structure is less than about 8 μm, effects of blocking moisture absorption or progressing of the crack may be decreased. When the width of the moat structure is greater than 10 μm, the number of semiconductor chips manufactured on the semiconductor substrate may decrease. Therefore, an integration degree of the semiconductor chip may be lowered.

Accordingly, the test element group pattern 240 and the moat structure 230 may not be disposed together in a width direction on the scribe lane region A2.

Referring to FIG. 9, the scribe lane region A2 of the semiconductor substrate 140 may be cut by a sawing process to form individual semiconductor chips 200. In the sawing process, a portion between the two moat structures 230 in the scribe lane region A2 may cut. A cut portion of the semiconductor substrate 140 may be a sidewall of the semiconductor chip 200. Accordingly, the sidewall of the semiconductor chip 200 may be positioned in the scribe lane region A2.

In some example embodiments, in a plan view, each of the semiconductor chips 200 formed on the semiconductor substrate 140 may have a shape the same as one of the semiconductor chips shown in FIGS. 3 to 5.

In some example embodiments, the semiconductor chips 200 may be provided as at least one of first to fourth semiconductor chips 200a, 200b, 200c, and 200d included in a semiconductor package. The first to fourth semiconductor chips 200a, 200b, 200c, and 200d may include the same or different types of semiconductor chips.

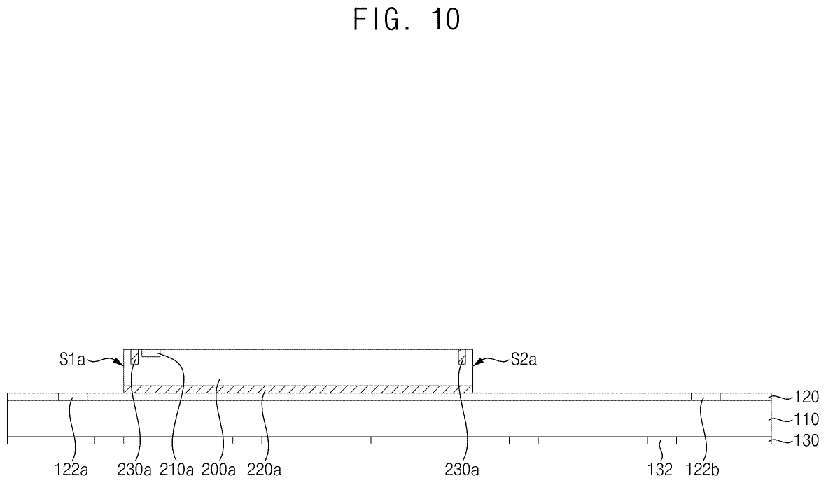

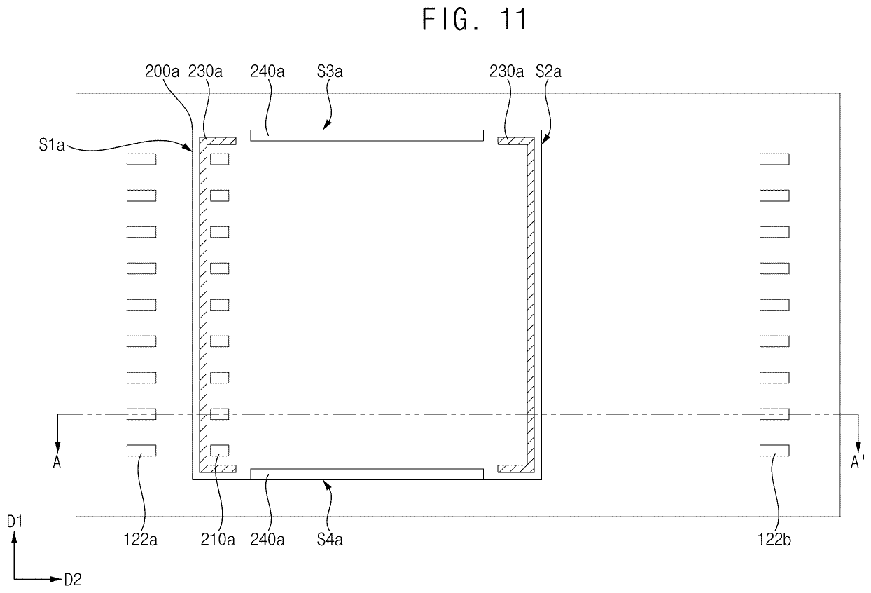

Referring to FIGS. 10 and 11, the first semiconductor chip 200a may be attached to the package substrate 110.

In a plan view, the first semiconductor chip 200a may have four sidewalls (Sla, S2a, S3a, and S4a). The first semiconductor chip 200a may include first chip pad patterns 210a disposed on a first semiconductor chip region adjacent to the first sidewall Sla.

A first moat structure 230a and a first test element group pattern 240a may be disposed on the scribe lane region A2 of the first semiconductor chip 200a. The first moat structure 230a may be disposed along at least the scribe lane region A2 adjacent to the first chip pad patterns 210a and the scribe lane region A2 facing the first chip pad patterns 210a. The first moat structure 230a may extend in the first direction D1. In a plan view, the first semiconductor chip 200a may have a shape the same as one of the semiconductor chips shown in FIGS. 3 to 5.

In some example embodiments, the package substrate 110 may be a printed circuit board (PCB). The printed circuit board may be a multilayer circuit board having via contact plugs and various circuits therein. The package substrate 110 may include internal wirings for electrical connection with a plurality of stacked semiconductor chips. First substrate pads 122a and second substrate pads 122b connected to the internal wirings may be disposed on an upper surface of the package substrate 110. External connection pads 132 for transmission of electrical signals may be disposed on a lower surface of the package substrate 110. The external connection pads 132 may be exposed by a second insulation layer 130.

The first adhesive member 220a may be interposed between the package substrate 110 and the first semiconductor chip 200a, and thus the first semiconductor chip 200a may be attached to the package substrate 110. In some example embodiments, the first semiconductor chip 200a may be attached to the package substrate 110 using a die attach film (DAF) through a die attach process.

In some example embodiments, the first semiconductor chip 200a may be a logic chip including logic circuits. The logic chip may be a controller that controls memory chips. The first semiconductor chip 200a may be a processor chip, for example, an ASIC or an application processor (AP) as a host such as a CPU, GPU, or SOC.

In some example embodiments, the first semiconductor chip 200a may include a memory chip including memory circuits. For example, the first semiconductor chip 200a may include volatile memory devices such as a SRAM device and a DRAM device, and a non-volatile memory device such as flash memory devices, a PRAM device, and an MRAM device, an RRAM device, etc.

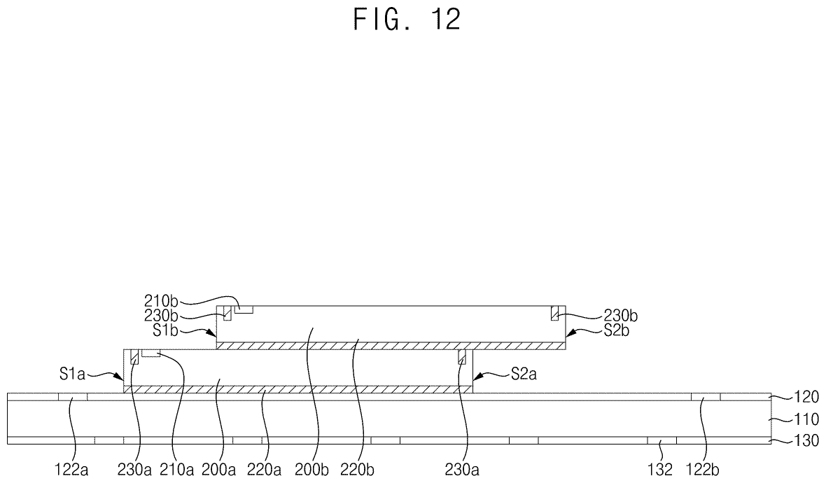

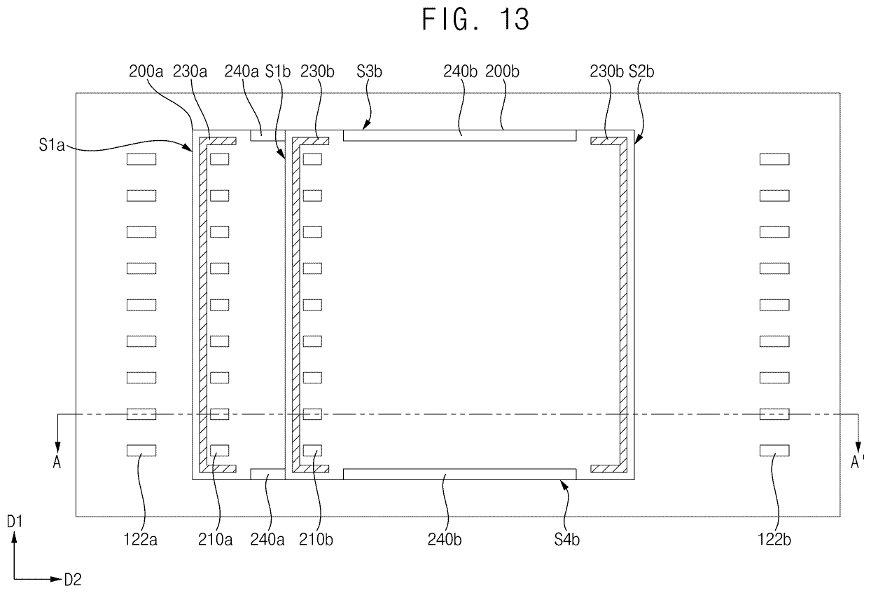

Referring to FIGS. 12 and 13, the second semiconductor chip 200b may be stacked on the first semiconductor chip 200a.

In a plan view, the second semiconductor chip 200b may have a rectangular shape having four sidewalls (S1b, S2b, S3b, and S4b). The second semiconductor chip 200b may have a shape the same as the shape of the first semiconductor chip 200a. Second chip pad patterns 210b of the second semiconductor chip 200b may be disposed on a second semiconductor chip region adjacent to the first sidewall S1b. A second moat structure 230b and a second test element group pattern 240b may be disposed on the scribe lane region of the second semiconductor chip 200b. The second moat structure 230b may be disposed along at least the scribe lane region adjacent to the second chip pad patterns 210b and the scribe lane region facing the second chip pad patterns 210b. The second moat structure 230b may extend in the first direction D1. In the plan view, the second semiconductor chip 200b may have a shape the same as one of the semiconductor chips shown in FIGS. 3 to 5.

In some example embodiments, the second semiconductor chip 200b may include the same type of memory chip as the first semiconductor chip 200a.

The second semiconductor chip 200b may be attached to the first semiconductor chip 200a using a second adhesive member 220b. In some example embodiments, the second semiconductor chip 200b may be attached to the first semiconductor chip 200a using a die attach film (DAF) through a die attach process.

In some example embodiments, some edges of the second semiconductor chip 200b may not be aligned with (e.g., may be offset from) some edges of the first semiconductor chip 200a. For example, the second semiconductor chip 200b may be stacked in a cascade manner.

The second semiconductor chip 200b may be offset in a horizontal direction on the first semiconductor chip 200a. In some example embodiments, the second semiconductor chip 200b may be offset in the second direction D2, so that the first chip pad patterns 210a of the first semiconductor chip 200a are exposed. Edges in the second direction D2 of the first and second semiconductor chips 200a and 200b may not be aligned to (e.g., may be offset from) each other.

The second sidewall S2b of the second semiconductor chip 200b may protrude laterally from the second sidewall S2a of the first semiconductor chip 200a. A portion adjacent to the second sidewall S2a and the second sidewall S2a of the first semiconductor chip 200a may be a first overhang region.

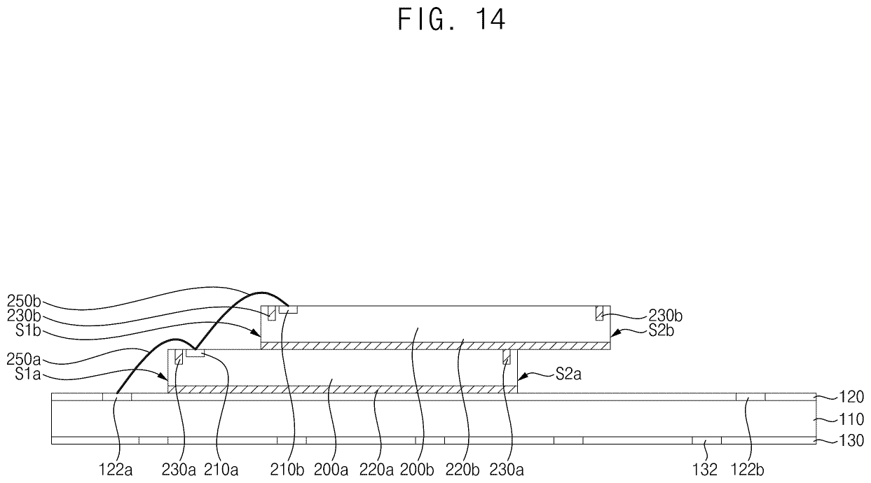

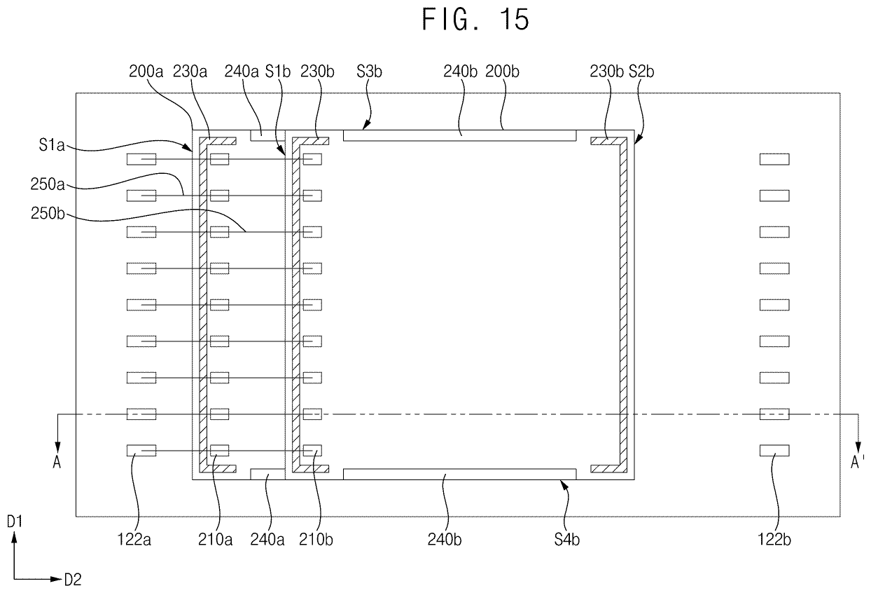

Referring to FIGS. 14 and 15, first bonding wirings 250a may be bonded on the first chip pad patterns 210a of the first semiconductor chip 200a and the upper surface of the package substrate 110 by a wire bonding process. Accordingly, the first chip pad patterns 210a of the first semiconductor chip 200a and the first substrate pads 122a on the upper surface of the package substrate 110 may be electrically connected by the first bonding wirings 250a.

Second bonding wirings 250b may be bonded on the second chip pad patterns 210b of the second semiconductor chip 200b and the first chip pad patterns 210a of the first semiconductor chip 200a by a wire bonding process. Accordingly, the second chip pad patterns, the first chip pad pattern 210a, and the first substrate pads 122a on the upper surface of the package substrate 110 may be electrically connected by the second bonding wirings 250b.

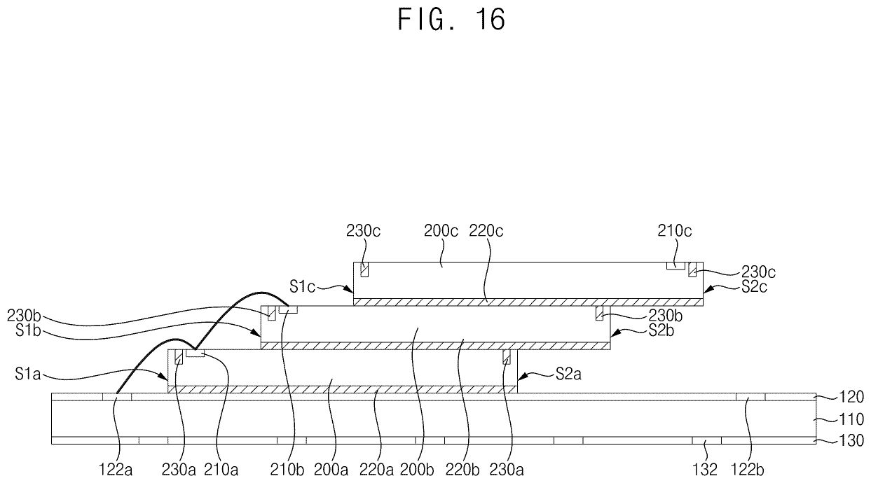

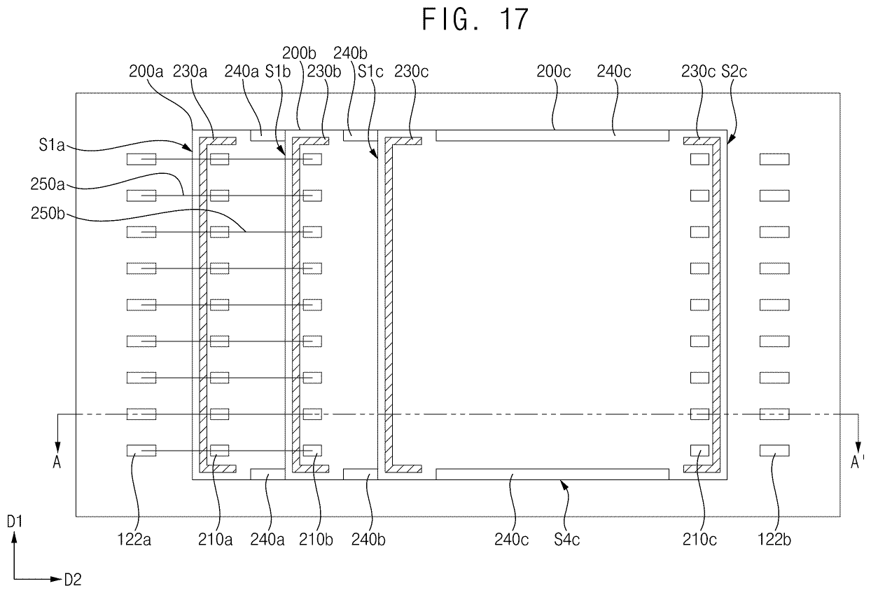

Referring to FIGS. 16 and 17, a third semiconductor chip 200c may be stacked on the second semiconductor chip 200b.

In a plan view, the third semiconductor chip 200c may have a rectangular shape with four sidewalls (S1c, S2c, S3c, and S4c). The third chip pad patterns 210c of the third semiconductor chip 200c may be disposed on the third semiconductor chip region adjacent to the first sidewall S1c. The third semiconductor chip 200c may have a third moat structure 230c and a third test element group pattern 240c disposed on the scribe lane region. The third moat structure 230c may be disposed along at least the scribe lane region adjacent to the third chip pad patterns 210c and the scribe lane region facing the third chip pad patterns 210c. The third moat structure 230c may extend in the first direction D1. In a plan view, the third semiconductor chip 200c may have a shape the same as one of the semiconductor chips shown in FIGS. 3 to 5.

In some example embodiments, the third semiconductor chip 200c may include the same type of memory chip as the second semiconductor chip 200b.

The third semiconductor chip 200c may be attached to the second semiconductor chip 200b using a third adhesive member 220c. In some example embodiments, the third semiconductor chip 200c may be attached to the second semiconductor chip 200b using a die attach film (DAF) through a die attach process.

In some example embodiments, the third semiconductor chip 200c may not be aligned with (e.g., may be offset from) the second semiconductor chip 200b. For example, the third semiconductor chip 200c may be stacked in a cascade manner.

The third semiconductor chip 200c may be offset in the horizontal direction on the second semiconductor chip 200b. The third semiconductor chip 200c may be offset in the second direction so that the second chip pad patterns 210b of the second semiconductor chip 200b may be exposed. The second and third semiconductor chips 200b and 200c may be stacked so that edges in the second direction D2 of the second and third semiconductor chips 200b and 200c may not be aligned to (e.g., may be offset from) each other.

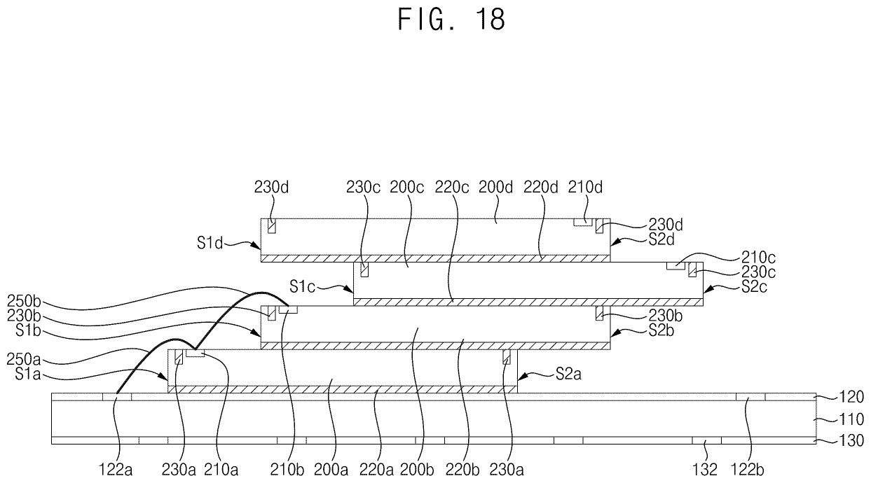

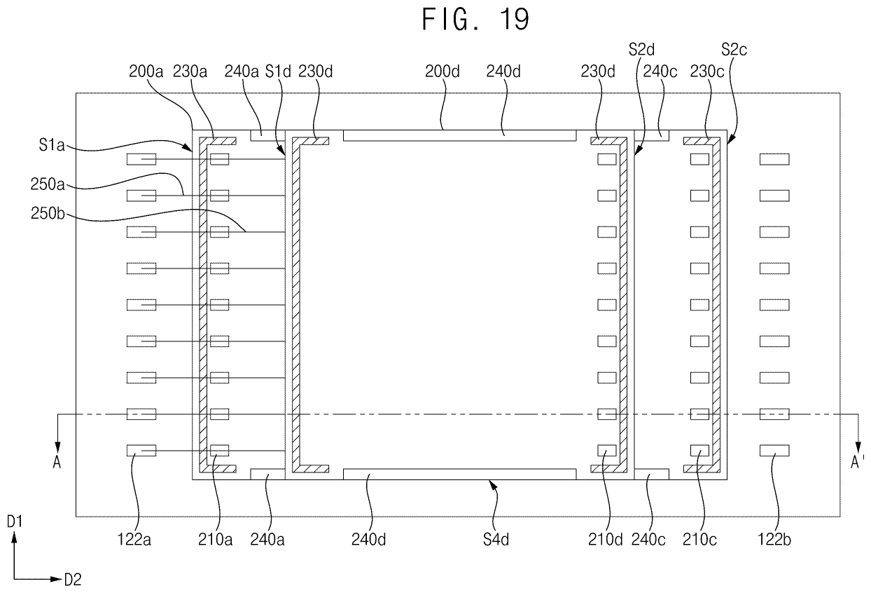

Referring to FIGS. 18 and 19, a fourth semiconductor chip 200d may be stacked on the third semiconductor chip 200c.

In a plan view, the fourth semiconductor chip 200d may have a rectangular shape having four sidewalls S1d, S2d, S3d, and S4d. Fourth chip pad patterns 210d included in the fourth semiconductor chip 200d may be disposed on a region adjacent to the second sidewall S2d of the fourth semiconductor chip. The fourth semiconductor chip 200d may have a fourth moat structure 230d and a fourth test device group pattern 240d disposed on the scribe lane region. The fourth moat structure 230d may be formed along at least a scribe lane region adjacent to the fourth chip pad patterns 210d and a scribe lane region facing the fourth chip pad patterns 210d. The fourth moat structure 230d may extend in the first direction D1. In the plan view, the fourth semiconductor chip 200d may have a shape the same as one of the semiconductor chips shown in FIGS. 3 to 5.

In some example embodiments, the fourth semiconductor chip 200d may include the same type of memory chip as the third semiconductor chip 200c.

The fourth semiconductor chip 200d may be attached to the third semiconductor chip 200c using a fourth adhesive member 220d. In some example embodiments, the fourth semiconductor chip 200d may be attached to the third semiconductor chip 200c using a die attach film (DAF) through a die attach process.

In some example embodiments, the fourth semiconductor chip 200d may not be aligned with (e.g., may be offset from) the third semiconductor chip 200c. For example, the fourth semiconductor chip 200d may be stacked in a cascade manner.

The fourth semiconductor chip 200d may be offset in the horizontal direction on the third semiconductor chip 200c. The fourth semiconductor chip 200d may be offset in the second direction so that the third chip pad patterns 210c of the third semiconductor chip 200c may be exposed. The third and fourth semiconductor chips 200c and 200d may be stacked so that edges in the second direction D2 of the third and fourth semiconductor chips 200c and 200d may not be aligned to (e.g., may be offset from) each other.

The second sidewall S2c of the third semiconductor chip 200c may protrude laterally from the second sidewall S2b of the second semiconductor chip 200b. A portion adjacent to the second sidewall S2b and the second sidewall S2b of the second semiconductor chip 200b may be a second overhang region.

The first sidewall S1d of the fourth semiconductor chip 200d may protrude laterally from the first sidewall Sc of the third semiconductor chip 200c. A portion adjacent to the first sidewall S1b and the first sidewall S1b of the second semiconductor chip 200b may be a third overhang region. A portion adjacent to the first sidewall S1c and the first sidewall S1c of the third semiconductor chip 200c may be a fourth overhang region.

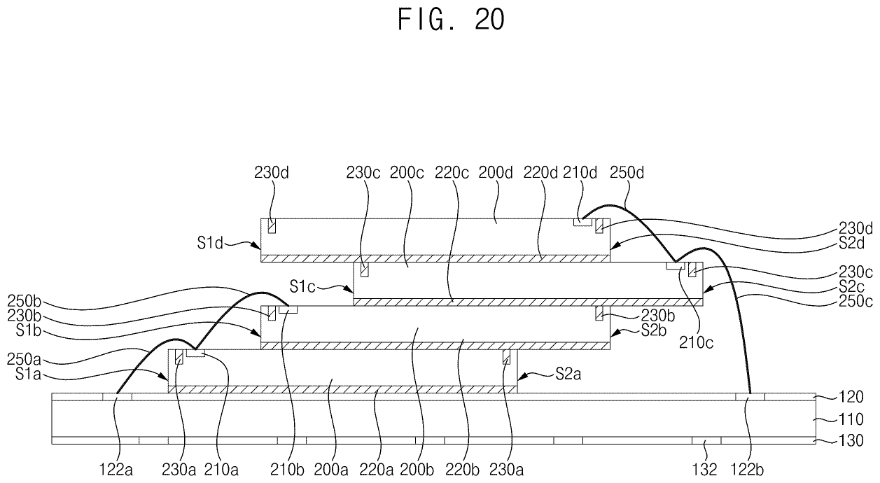

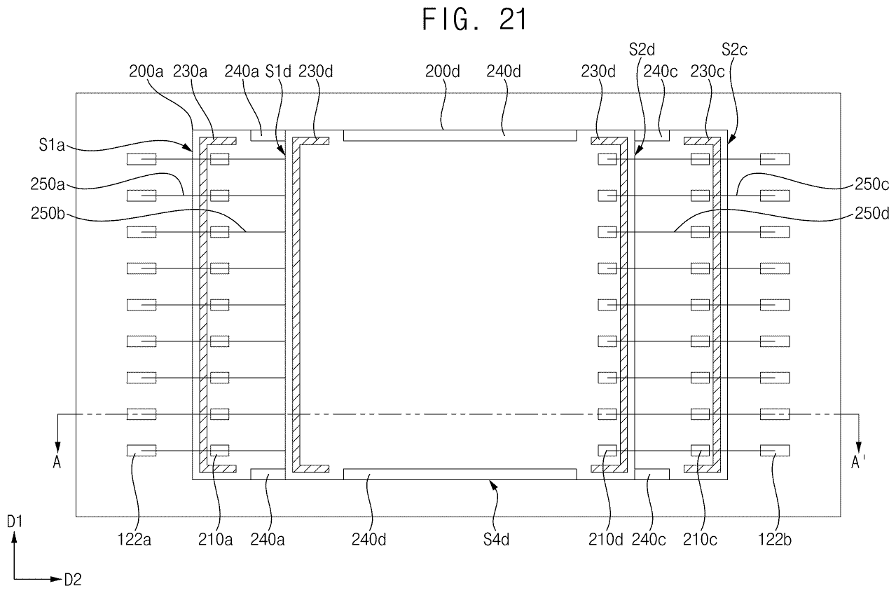

Referring to FIGS. 20 and 21, third bonding wirings 250c may be bonded on the third chip pad patterns 210c of the third semiconductor chip 200c and the upper surface of the package substrate 110 by a wire bonding process. Accordingly, the third chip pad pattern 210c of the third semiconductor chip 200c and the second substrate pads 122b on the upper surface of the package substrate 110 may be electrically connected by the third bonding wirings 250c.

Fourth bonding wirings 250d may be bonded on the fourth chip pad patterns 210d of the fourth semiconductor chip 200d and the third chip pad patterns 210c of the upper surface of the third semiconductor chip 200c. Accordingly, the fourth chip pad pattern 210d, the third chip pad pattern 210c, and the second substrate pads 122b on the upper surface of the package substrate 110 may be electrically connected by the fourth bonding wirings 250d.

As described above, the moat structures 230a, 230b, 230c, 230d included in each of the first to fourth semiconductor chips 200a, 200b, 200c, 200d may be disposed on the scribe lane region adjacent to the chip pad patterns and the scribe lane region facing the chip pad patterns. The scribe lane region adjacent to the chip pad patterns and the scribe lane region facing the chip pad patterns may include the first to fourth overhang regions.

The moat structures 230a, 230b, 230c, and 230d may be disposed on the regions where the crack defects due to hygro-swelling most frequently occur in the semiconductor chips 200a, 200b, 200c, and 200d. Therefore, the crack defects in the semiconductor chips 200a, 200b, 200c, and 200d may be decreased. Additionally, the test element group patterns 240 may be disposed on the scribe lane region where the moat structures 230a, 230b, 230c, and 230d are not formed.

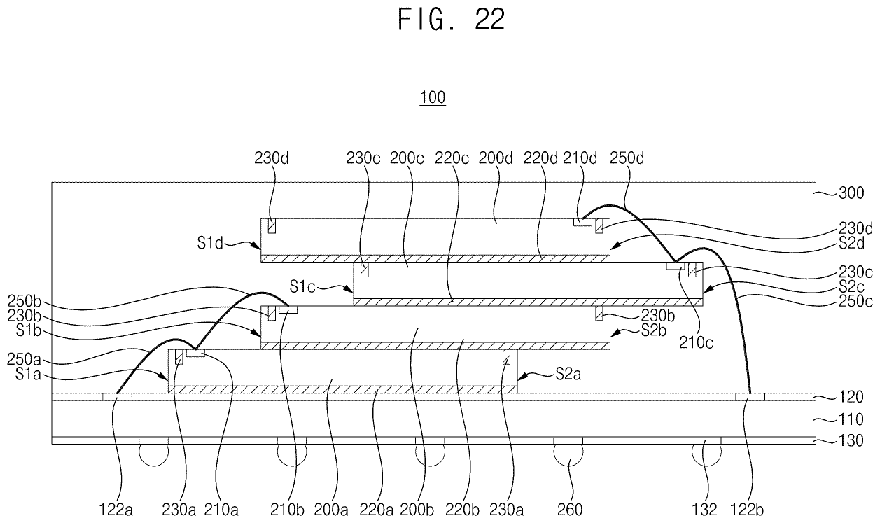

Referring to FIG. 22, a sealing member 300 may be formed on the upper surface of the package substrate 110 to cover the first to fourth semiconductor chips 200a, 200b, 200c, 200d and the first to fourth bonding wirings 250a, 250b. The sealing member 300 may include a thermosetting resin, e.g., epoxy mold compound (EMC).

External connection members 260 may be formed on the external connection pads 132 on the lower surface of the package substrate 110 so that the semiconductor package 100 shown in FIG. 1 may be manufactured.

For example, the external connection members 260 may include solder balls. The external connection members 260 may be formed on the external connection pads 132 on the lower surface of the package substrate 110 through a solder ball attach process.

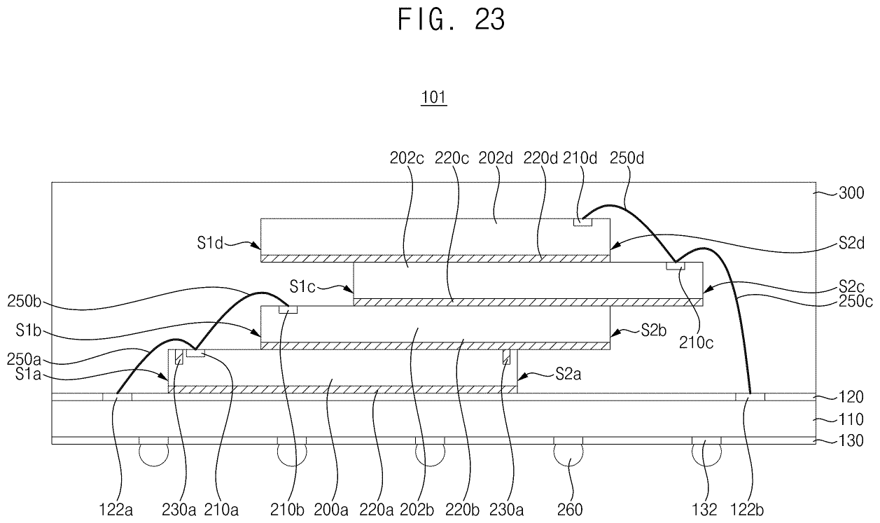

FIG. 23 is a cross-sectional view showing a semiconductor package according to an example embodiment.

The semiconductor package is the same as or substantially similar to as the semiconductor package described with reference to FIGS. 1 and 2, except for arrangements of the moat structure and the test element group pattern included in the second to fourth semiconductor chips. Accordingly, the same components may be indicated by the same reference numerals, and repeated descriptions of the same components may be omitted.

Referring to FIG. 23, in the semiconductor package 101, the first semiconductor chip 200a disposed at a bottom may include the moat structure and the test element group pattern described with reference to FIGS. 1 and 2. For example, a configurations and an arrangement of each of the moat structure and the test element group pattern included in the first semiconductor chip may be the same as or substantially similar to those of the described with reference to FIGS. 1 and 2.

The first semiconductor chip 200a may include the first moat structure 230a and the first test element group pattern. The first moat structure 230a may be disposed on at least the scribe lane region A2 adjacent to the first chip pad patterns 210a and on the scribe lane region A2 facing the first chip pad patterns 210a. The first moat structure 230a may extend in the first direction D1. In the plan view, the first semiconductor chip 200a may have a shape the same as one of the semiconductor chips shown in FIGS. 3 to 5.

In each of the second to fourth semiconductor chips 202b, 202c, and 202d stacked on the first semiconductor chip 200a, a moat structure and a test element group pattern may be randomly arranged in the scribe lane region. For example, the moat structure included in each of the second to fourth semiconductor chips 202b, 202c, and 202d may not be disposed along the scribe lane region adjacent to the chip pad patterns and the scribe lane region facing the chip pad patterns. For example, the test element group pattern included in each of the second to fourth semiconductor chips 202b, 202c, and 202d may be disposed on a scribe lane region adjacent to the chip pad patterns and on the scribe lane region facing the chip pad patterns 210.

The first semiconductor chip 200a disposed at the bottom may have more crack defects due to the hygro-swelling than the second to fourth semiconductor chips 202b, 202c, and 202d disposed above the first semiconductor chip 200a. Accordingly, the first moat structure 230a included in the first semiconductor chip 200a may be disposed along the scribe lane region A2 adjacent to the first chip pad patterns and the scribe lane region A2 facing the chip pad patterns 210, described above. Therefore, the crack defects of semiconductor chip 200a the may be decreased.

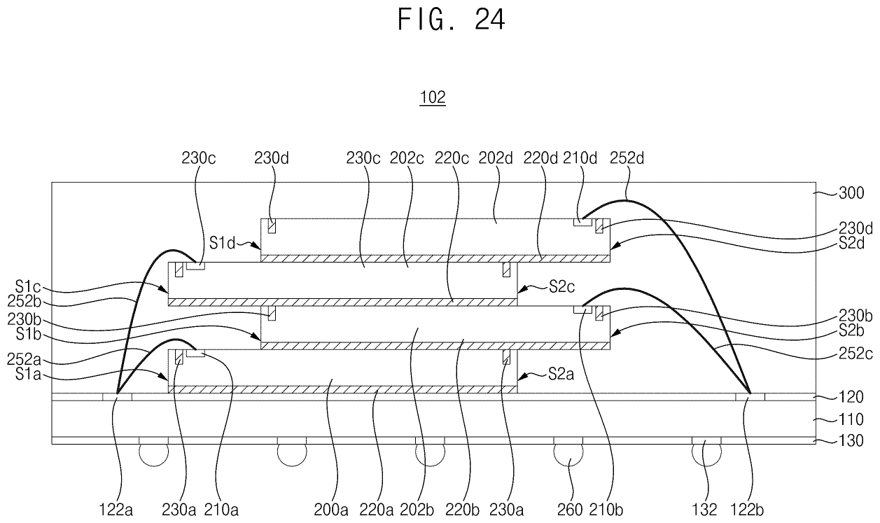

FIG. 24 is a cross-sectional view illustrating a semiconductor package according to an example embodiment.

The semiconductor package may be the same as or substantially similar to the semiconductor package described with reference to FIGS. 1 and 2, except for a stacked structure and a connection structure of the first to fourth semiconductor chips. Accordingly, the same components may be indicated by the same reference numerals, and repeated descriptions of the same components may be omitted.

Referring to FIG. 24, the semiconductor package 102 may include the first to fourth semiconductor chips 200a, 200b, 200c, and 200d sequentially stacked.

In some example embodiments, in a plan view, the first to fourth semiconductor chips 200a, 200b, 200c, and 200d may have a shape the same as one of the semiconductor chips shown in FIGS. 3 to 5. Each of the first to fourth semiconductor chips 200a, 200b, 200c, and 200d may include the moat structures 230a, 230b, 230c, and 230d and the test element group patterns 240 (referred to as FIG. 3).

For example, as shown in FIG. 3, the moat structure 230 may be disposed along at least a scribe lane region A2 adjacent to the chip pad patterns 210 and the scribe lane region A2 facing the chip pad patterns 210. The moat structure 230 may extend in the first direction D1.

The first to fourth semiconductor chips 200a, 200b, 200c, and 200d may be stacked in a zigzag manner.

The second semiconductor chip 200b may be stacked on the first semiconductor chips 200a so that ends in the second direction of the second semiconductor chip 200b may not be aligned with (e.g., may be offset from) ends in the second direction of the first semiconductor chip 200a. In some example embodiments, the second semiconductor chip 200b may be stacked on the first semiconductor chip 200a in the zigzag manner. The second semiconductor chip 200b may be offset in the second direction on the first semiconductor chip 200a. The second semiconductor chip 200b may be offset in the second direction D2 so that the first chip pad patterns 210a of the first semiconductor chip 200a may be exposed.

The third semiconductor chip 200c may be stacked on the second semiconductor chip 200b so that ends in the second direction of the third semiconductor chip 200c may not be aligned with (e.g., may be offset from) the ends in the second direction of the second semiconductor chip 200b. In some example embodiments, the third semiconductor chip 200c may be stacked on the second semiconductor chip 200b in the zigzag manner. For example, the third semiconductor chip 200c may completely overlap the first semiconductor chip 200a. The ends in the second direction of the third semiconductor chip 200c may be aligned with ends in the second direction of the first semiconductor chip 200a.

The fourth semiconductor chip 200d may be stacked on the third semiconductor chip 200c so that ends in the second direction of the fourth semiconductor chip 200d may not be aligned with (e.g., may be offset from) the ends in the second direction of the third semiconductor chip 200c. In some example embodiments, the fourth semiconductor chip 200d may be stacked on the third semiconductor chip 200c in the zigzag manner. The fourth semiconductor chip 200d may completely overlap the second semiconductor chip 200b. The ends in the second direction of the fourth semiconductor chip 200d may be aligned with ends in the second direction of the second semiconductor chip 200b.

The first semiconductor chip 200a may be electrically connected to the package substrate 110 by the first bonding wiring 252a. The first bonding wiring 252a may contact the first chip pad pattern 210a and the first substrate pad 122a.

The second semiconductor chip 200b may be electrically connected to the package substrate 110 by the second bonding wiring 252b. The second bonding wiring 252b may contact the second chip pad pattern 210b and the second substrate pad 122b.

The third semiconductor chip 200c may be electrically connected to the package substrate 110 by the third bonding wiring 252c. The third bonding wiring 252c may contact the third chip pad pattern 210c and the first substrate pad 122a.

The fourth semiconductor chip 200d may be electrically connected to the package substrate 110 by the fourth bonding wiring 252d. The fourth bonding wiring 252d may contact the fourth chip pad pattern 210d and the second substrate pad 122b.

The second semiconductor chip 200b may laterally protrude (e.g., in the second direction) from the second sidewalls S2a and S2c of the first and third semiconductor chips 200a and 200c. The fourth semiconductor chip 200d may protrude laterally from the second sidewall S2c of the third semiconductor chip 200c.

A portion adjacent to the second sidewall S2a and the second sidewall S2a of the first semiconductor chip 200a disposed below the protruding second semiconductor chip 200b may be a first overhang region. A portion adjacent to the first sidewall Sla and the first sidewall Sla of the first semiconductor chip 200a disposed below the protruding third semiconductor chip 200c may be a second overhang region. A portion adjacent to the second sidewall S2b and the second sidewall S2b of the second semiconductor chip 200b disposed below the protruding fourth semiconductor chip 200d may be a third overhang region. A portion adjacent to the first sidewall S1b and the first sidewall S1b of the second semiconductor chip 200b disposed below the protruding third semiconductor chip 200c may be a fourth overhang region. A portion adjacent to the second sidewall S2c and the second sidewall S2c of the third semiconductor chip 200c disposed below the protruding fourth semiconductor chip 200d may be a fifth overhang region. The overhang regions of each of the semiconductor chips 200 may be disposed along at least the edges in the second direction D2 of the semiconductor chips 200.

At least portions of the regions where the first to fourth moat structures 230a, 230b, 230c, and 230d are formed may correspond to the overhang regions of each of the semiconductor chips 200 included in the semiconductor package 102. The first to fourth moat structures 230a, 230b, 230c, and 230d may be disposed on the overhang regions of each of the semiconductor chips 200.

The first to fourth moat structures 230a, 230b, 230c, and 230d may be disposed on the overhang region where crack defects due to the hygro-swelling most frequently occur in the semiconductor chip 200. Therefore, crack defects in the first to fourth semiconductor chips 200a, 200b, 200c, and 200d may be decreased. In each of the semiconductor chips 200, the test element group patterns 240 may be disposed on the scribe lane region A2 where the moat structure is not formed.

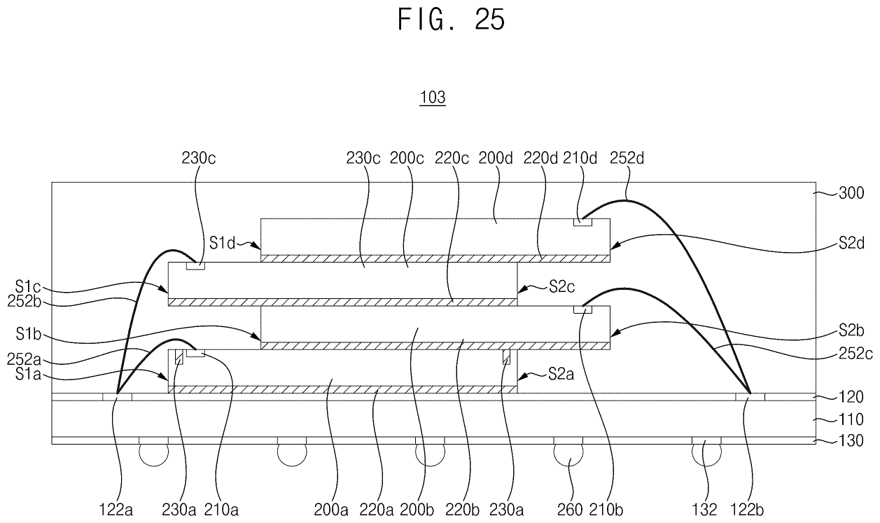

FIG. 25 is a cross-sectional view illustrating a semiconductor package according to an example embodiment.

The semiconductor package may be the same as or substantially similar to the semiconductor package described with reference to FIG. 24, except for arrangements of the moat structure and the test element group pattern included in each of the second to fourth semiconductor chips. Accordingly, the same components may be indicated by the same reference numerals, and repeated descriptions of the same components may be omitted.

Referring to FIG. 25, in the semiconductor package 103, the first semiconductor chip 200a disposed at the bottom may have the same as the moat structure and the test element group pattern described with reference to FIGS. 1 and 2. For example, a configurations and an arrangement of each of the moat structure and the test element group pattern included in the first semiconductor chip may be the same as or substantially similar to those of the described with reference to FIGS. 1 and 2.

The first semiconductor chip 200a may include the first moat structure 230a and the first test element group pattern. The first moat structure 230a may be disposed along at least the scribe lane region A2 adjacent to the first chip pad patterns 210a and the scribe lane region A2 facing the first chip pad patterns 210a. The first moat structure 230a may extend in the first direction D1. In the plan view, the first semiconductor chip 200a may have a shape the same as one of the semiconductor chips shown in FIGS. 3 to 5.

In the second to fourth semiconductor chips 202b, 202c, and 202d disposed on the first semiconductor chip 200a, the moat structure and the test element group pattern may be randomly arranged in the scribe lane region A2. For example, the moat structure included in each of the second to fourth semiconductor chips 202b, 202c, and 202d may not be disposed on the scribe lane region A2 adjacent to the chip pad patterns and on the scribe lane region facing the chip pad patterns. For example, the test element group pattern may be disposed on the scribe lane region adjacent to the chip pad patterns and on the scribe lane region facing the chip pad patterns.

The first semiconductor chip 200a disposed at the bottom may occur more crack defects due to the hygro-swelling than the semiconductor chips disposed above the first semiconductor chip 200a. Accordingly, the first moat structure 230a included in the first semiconductor chip 200a may be disposed on the scribe lane region A2 adjacent to the first chip pad patterns 210a and the scribe lane region A2 facing the first chip pad patterns 210a, so that the crack defects of the first semiconductor chip 200a may be decreased.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of the present inventive concepts.

What is claimed is:

1. A semiconductor package, comprising:
a package substrate including substrate pads;
a plurality of semiconductor chips stacked on an upper surface of the package substrate;
bonding wirings electrically connecting the plurality of semiconductor chips and the substrate pads of the package substrate to each other; and
a sealing member on the upper surface of the package substrate and covering the plurality of semiconductor chips,
wherein each of the plurality of semiconductor chips comprises
a semiconductor substrate including first and second edges facing each other, the first and second edges extending in a first direction,
chip pad patterns on a portion of a semiconductor chip region of the semiconductor substrate that is adjacent to the first edge, the chip pad patterns being along the first edge, and
a moat structure including a plurality of moat structures, the plurality of moat structures including a first moat structure and a second moat structure, the first moat structure being on a first scribe lane region of the semiconductor substrate that is adjacent to the chip pad patterns and the second moat structure being on a second scribe lane region of the semiconductor substrate that is adjacent to the second edge, and
wherein the first moat structure extends along the first edge, and the second moat structure extends along the second edge.

2. The semiconductor package of claim 1, further comprising:
a test element group pattern on another scribe lane region between the plurality of moat structures, in each of the semiconductor chips.

3. The semiconductor package of claim 2, wherein
the semiconductor chip region includes a third edge and a fourth edge extending in a second direction perpendicular to the first direction and facing each other, and
the test element group pattern is on a third scribe lane region adjacent to the third edge and on a fourth scribe lane region adjacent to the fourth edge.

4. The semiconductor package of claim 1, wherein a group of the plurality of moat structures included in at least one of the semiconductor chips are symmetrical to each other.

5. The semiconductor package of claim 1, wherein
the first moat structure is spaced apart from the first edge, and continuously extends along an entirety of the first edge, and
wherein the second moat structure is spaced apart from the second edge, and continuously extends along an entirety of the second edge.

6. The semiconductor package of claim 1, wherein
the first moat structure extends continuously within the first scribe lane region, and
the second moat structure extends continuously within the second scribe lane region.

7. The semiconductor package of claim 1, wherein each of the plurality of moat structures has a structure in which a protective insulation structure is filled in a trench of a lower structure on a corresponding one of the first scribe lane region and the second scribe lane region.

8. The semiconductor package of claim 7, wherein the protective insulation structure includes a metal barrier pattern, a capping insulation layer, and an upper protective layer.

9. The semiconductor package of claim 8, wherein the upper protective layer includes photosensitive polyimide (PSPI).

10. The semiconductor package of claim 1, wherein a width of each of the plurality of moat structures is in a range of 8 μm to 10 μm.

11. The semiconductor package of claim 1, wherein edges in a second direction, which is perpendicular to the first direction, of adjacent semiconductor chips from among the plurality of semiconductor chips, are offset from each other.

12. The semiconductor package of claim 1, wherein some sidewalls of adjacent semiconductor chips from among the plurality of semiconductor chips laterally protrude and define an overhang region.

13. A semiconductor package, comprising:
a package substrate including substrate pads;
a plurality of semiconductor chips stacked on an upper surface of the package substrate, and including chip pad patterns, moat structures, and test element group patterns;
bonding wirings electrically connecting chip pad patterns of the plurality of semiconductor chips and the substrate pads of the package substrate to each other; and
a sealing member on the upper surface of the package substrate and covering the plurality of semiconductor chips,
wherein each of the plurality of semiconductor chips includes a semiconductor chip region and a scribe lane region surrounding the semiconductor chip region, the semiconductor chip region including a first edge, a second edge, a third edge, and a fourth edge, the first and second edges extending in a first direction and facing each other, the third and fourth edges extending in a second direction perpendicular to the first direction and facing each other,
wherein the chip pad patterns are on a portion of the semiconductor chip region that is adjacent to the first edge, and the chip pad patterns are spaced apart from each other in the first direction,
wherein the scribe lane region includes a first scribe lane region adjacent to the chip pad patterns and a second scribe lane region adjacent to the second edge of the semiconductor chip region,
wherein the moat structures include a first moat structure and a second moat structure, the first moat structure being on the first scribe lane region, the second moat structure being on the second scribe lane region, and each of the moat structures extending in the first direction, and
wherein the test element group patterns are on one or more scribe lane regions other than the first scribe lane region and the second scribe lane region.

14. The semiconductor package of claim 13, wherein edges in the second direction of adjacent semiconductor chips from among the plurality of semiconductor chips are offset from each other.

15. The semiconductor package of claim 13, wherein the first moat structure is spaced apart from the first edge and continuously extends along an entirety of the first edge, and the second moat structure is spaced apart from and continuously extends along an entire of the second edge.

16. The semiconductor package of claim 13, wherein the scribe lane region further includes a third scribe lane region adjacent to the third edge and a fourth scribe lane region adjacent to the fourth edge, the test element group patterns are on at least one of the third scribe lane region or the fourth scribe lane region.

17. The semiconductor package of claim 16, wherein the first moat structure extends along an entirety of the first scribe lane region and portions of the third and fourth scribe lane regions, and the second moat structure extends along an entirety of the second scribe lane region and portions of the third and fourth scribe lane region.

18. The semiconductor package of claim 13, wherein each of the moat structures has a structure in which a protective insulation structure is filled in a trench of a lower structure on the scribe lane region.

19. The semiconductor package of claim 13, wherein a group of the moat structures included in at least one of the semiconductor chips are symmetrical to each other.

20. A semiconductor package, comprising:
a package substrate including substrate pads;
a plurality of semiconductor chips stacked on an upper surface of the package substrate, some edges of adjacent semiconductor chips from among the plurality of semiconductor chips are offset from each other;
bonding wirings electrically connecting the plurality of semiconductor chips and the substrate pads of the package substrate to each other; and
a sealing member on the upper surface of the package substrate and covering the plurality of semiconductor chips,
wherein at least one of the plurality of semiconductor chips comprises,
chip pad patterns along a first edge of a semiconductor chip region thereof,
moat structures on a first scribe lane region adjacent to the chip pad patterns and a second scribe lane region adjacent to a second edge facing the first edge of the semiconductor chip region, and
a test element group pattern on a third scribe lane region between the moat structures.
